(19) United States
(12) Patent Application Publication
(10) Pub. No.: US 2026/0291179 A1
(43) Pub. Date: Sep. 24, 2026

(54) LIGHT-EMITTING MODULE AND OPTICAL DEVICE

(71) Applicant: TDK CORPORATION, Tokyo (JP)

(72) Inventors: Hiroshi TAKE, Hong Kong (CN); Takashi HONDA, Tokyo (JP); Tetsuya MINO, Hong Kong (CN); Taku KOSUGE, Hong Kong (CN); Ryohei FUKUZAKI, Hong Kong (CN)

(73) Assignee: TDK CORPORATION, Tokyo (JP)

(21) Appl. No.: 19/574,696

(22) Filed: Mar. 23, 2026

(30) Foreign Application Priority Data
Mar. 24, 2025 (JP) 2025-048024

(51) Int. Cl. H01S 5/06; H01S 5/02315; H01S 5/40

(52) U.S. Cl. CPC H01S 5/0612; H01S 5/02315; H01S 5/4093

(57) ABSTRACT

A light-emitting module includes: a carrier; a laser diode fixed to one surface of the carrier; and a temperature detecting unit that is formed on the one surface and includes a unit pattern including a first wiring extending in a first direction away from the laser diode in a planar direction of the one surface and a second wiring connected to the first wiring, extending in a second direction perpendicular to the first direction, and having a length in the second direction being longer than a length of the first wiring in the first direction.

### CROSS REFERENCE TO RELATED APPLICATION

This application claims the benefit of Japanese Priority Patent Application No. 2025-048024 filed on Mar. 24, 2025, the entire contents of which are incorporated herein by reference.

### FIELD

The present disclosure relates to a light-emitting module and an optical device.

### BACKGROUND

A technique is known for detecting the temperature of a laser diode fixed to a carrier and controlling emission of light by the laser diode. A temperature detecting unit that detects the temperature of the laser diode is desirably installed in a vicinity of the laser diode to enable accurate temperature detection. For example, according to Patent Publication JP-A-2000-349383, the temperature detecting unit is embedded in a lower layer of a substrate, and a laser diode to be detected is arranged on an upper layer of the substrate so as to be positioned above the temperature detecting unit.

Configurations where a plurality of layers of substrates are stacked on a carrier are complex and increase cost. On the other hand, a light-emitting module introduced as related art in Patent Publication JP-A-2000-349383 has a simple configuration where a laser diode and a temperature detecting unit are placed side by side on a carrier. However, Patent Publication JP-A-2000-349383 points out that because the temperature detecting unit is positioned on one side of the laser diode, heat transfer from the laser diode to the temperature detecting unit tends to be uneven, thereby impairing trackability of temperature detection and creating a problem in terms of detection accuracy.

One aspect of the present disclosure has been made in order to solve the problem described above and an object thereof is to provide a light-emitting module equipped with a temperature detecting unit capable of accurately detecting the temperature of a laser diode with a simple configuration and an optical device equipped with the light-emitting module and capable of realizing output of preferable mixed-color light.

### SUMMARY

A light-emitting module according to a first aspect of the present disclosure includes: a carrier; a laser diode fixed to one surface of the carrier; and a temperature detecting unit that is formed on the one surface and includes a unit pattern including a first wiring extending in a first direction away from the laser diode in a planar direction of the one surface and a second wiring connected to the first wiring, extending in a second direction perpendicular to the first direction, and having a length in the second direction being longer than a length of the first wiring in the first direction.

In addition, an optical device according to a second aspect of the present disclosure includes: the light-emitting module described above; a waveguide module including a waveguide layer having an optical waveguide that propagates light emitted from a laser diode; and a control unit configured to control light intensity output by the laser diode based on a signal from the temperature detecting unit in the light-emitting module.

According to the present disclosure, a light-emitting module equipped with a temperature detecting unit capable of accurately detecting the temperature of a laser diode with a simple configuration and an optical device equipped with the light-emitting module and capable of realizing output of preferable mixed-color light can be provided.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a schematic view illustrating a configuration of a projector adopting an optical device according to a first example of the present example embodiment;

FIGS. 2A and 2B are a plan view and a front view of the optical device;

FIG. 3 is a diagram schematically showing a configuration of a temperature detecting unit;

FIG. 4 is a graph showing a change in resistance values over time when using a temperature detecting unit according to related art and a temperature detecting unit according to the first example;

FIG. 5 is a diagram schematically showing a configuration of a temperature detecting unit according to a first modification;

FIG. 6 is a diagram schematically showing a configuration of a temperature detecting unit according to a second modification;

FIG. 7 is a diagram schematically showing a configuration of a temperature detecting unit according to a third modification; and

FIG. 8 is a schematic view illustrating a configuration of a projector adopting an optical device according to a second example of the present example embodiment.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

An example embodiment of the present disclosure will be described with reference to the accompanying drawings. Elements designated by same reference signs in the respective drawings share an identical or a similar configuration. Note that the disclosure related to the scope of claims is not limited to the example embodiment described below. In addition, not all of the components described in the example embodiment are essential as means for solving the problem.

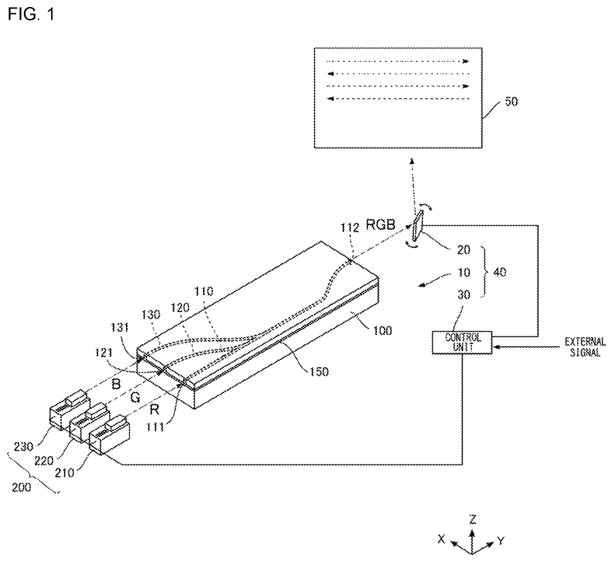

FIG. 1 is a schematic view illustrating a configuration of a projector 40 adopting an optical device 10 according to the first example of the present example embodiment. The projector 40 is mainly constituted of an optical device 10, a MEMS (Micro Electro Mechanical Systems) mirror 20, and a control unit 30. When the control unit 30 receives an external signal for generating an image from an external apparatus, the control unit 30 transmits a light emission control signal to the optical device 10 and causes the optical device 10 to generate light corresponding to the image. In doing so, the control unit 30 adjusts the light emission control signal based on a temperature detected in the optical device 10. A specific adjustment method and the like will be described in detail later. The MEMS mirror 20 continuously changes an orientation of its mirror surface in accordance with drive signals received from the control unit 30 to reflect light emitted from the optical device 10 so that a screen 50 is scanned with the light. The projector 40 projects images according to external signals in this manner onto the screen 50.

The optical device 10 is mainly constituted of a waveguide module 100 and a light-emitting module 200. In the present example embodiment, the light-emitting module 200 is made up of three light-emitting modules: a red light-emitting module 210, a green light-emitting module 220, and a blue light-emitting module 230. While the light-emitting modules are integrated by being joined to an end surface of the waveguide module 100 as will be described later, in the drawing, each light-emitting module is drawn separated from the end surface of the waveguide module 100.

The waveguide module 100 has a shape of a rectangular parallelepiped as a whole and, in the drawing, a lateral direction among planar directions is defined as an X-axis direction, a longitudinal direction among the planar directions is defined as a Y-axis direction, and a height direction orthogonal to the planar directions is defined as a Z-axis direction. Note that in subsequent drawings, similar coordinate axes with respect to the state in which the waveguide module 100 is installed as shown in FIG. 1 are shown together to indicate an orientation of a structure represented by each drawing.

The waveguide module 100 has a waveguide layer 150 parallel to an XY plane. The waveguide layer 150 is formed of an electro-optical material such as lithium niobate, and partial removal of a portion of the electro-optical material by etching or the like leaves a ridge portion that is convex in a cross-section. The ridge portion functions as an optical waveguide through which laser light propagates, and in the present example embodiment, three optical waveguides are formed as a part of the waveguide layer: a first optical waveguide 110, a second optical waveguide 120, and a third optical waveguide 130.

The first optical waveguide 110 is continuous by a straight line or a gentle curve from a first incidence end surface 111 which is exposed on one side surface of the waveguide module 100 to an exit end surface 112 which is exposed on one side surface on an opposite side of the waveguide module 100. In other words, laser light incident on the first incidence end surface 111 propagates along the first optical waveguide 110 and exits from the exit end surface 112.

The second optical waveguide 120 is continuous by a straight line or a gentle curve from a second incidence end surface 121 which is exposed on the one side surface of the waveguide module 100 provided with the first incidence end surface 111 until merging with a middle portion of the first optical waveguide 110. In other words, laser light incident on the second incidence end surface 121 propagates along the second optical waveguide 120, merges with the first optical waveguide 110 along the way, and exits from the exit end surface 112.

The third optical waveguide 130 is continuous by a straight line or a gentle curve from a third incidence end surface 131 which is exposed on the one side surface of the waveguide module 100 provided with the first incidence end surface 111 until merging with the middle portion of the first optical waveguide 110. In other words, laser light incident on the third incidence end surface 131 propagates along the third optical waveguide 130, merges with the first optical waveguide 110 along the way, and exits from the exit end surface 112.

Note that a configuration of the three optical waveguides is not limited to the example described above and need only be a configuration in which each optical waveguide has an incidence end surface, and the optical waveguides merge along the way and share a common exit end surface. Alternatively, a configuration may be adopted with two or more exit end surfaces due to branching downstream from where the three optical waveguides merge.

Since the second optical waveguide 120 and the third optical waveguide 130 merge with the first optical waveguide 110, when a plurality of laser diodes simultaneously emit light, a mixed-color light of the laser diodes is emitted from the exit end surface 112. More specifically, when causing a red laser diode 211, a green laser diode 221, and a blue laser diode 231 to emit light while controlling emission intensity of each laser diode, light of any target color can be emitted from the exit end surface 112. In addition, a monitor output (not illustrated in FIG. 1) may be provided at a location other than the exit end surface 112 to output mixed-color light or monochromatic light. Accordingly, the control unit 30 can adjust the light emission control signal so as to output desired light while monitoring the monitor output as feedback.

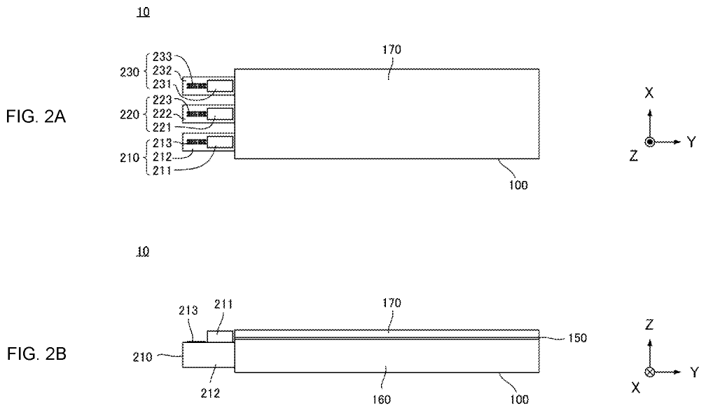

FIG. 2 is a plan view (FIG. 2A) and a front view (FIG. 2B) of the optical device 10. As shown in the front view, the waveguide module 100 includes a substrate 160 as a base layer, the waveguide layer 150 stacked on the substrate 160, and a buffer layer 170 as a cover layer which covers the waveguide layer. For example, a Si substrate or a sapphire substrate is used as the substrate 160. The buffer layer 170 is formed of a highly transparent material with a lower refractive index than that of the waveguide layer 150 and, for example, alumina (Al₂O₃) is used. While a space removed from the waveguide layer 150 by etching or the like in order to form an optical waveguide is also filled with the buffer layer 170 in the present example embodiment, alternatively, the space may be formed as a protective layer made of, for example, silicon dioxide (SiO₂). In addition, in the present example embodiment, while the substrate 160 is adopted as the base layer and the buffer layer 170 as the cover layer, at least one of the substrate 160 and the buffer layer 170 may be substituted for a cladding layer or configured together with the cladding layer. The cladding layer is formed of a material with a lower refractive index than that of the waveguide layer 150 and, for example, yttrium oxide (Y₂O₃) is used.

The red light-emitting module 210 is mainly constituted of the red laser diode 211, a first carrier 212, and a first temperature detecting unit 213. The red laser diode 211 is fixed to a fixing surface being an upper surface of the first carrier 212 toward a side of the waveguide module 100. The red laser diode 211 emits red laser light at an intensity corresponding to the light emission control signal sent from the control unit 30. The red laser light emitted from the red laser diode 211 is incident on the first incidence end surface 111 of the first optical waveguide 110.

The first carrier 212 is a block body formed of a material with an electrical insulation property. The first temperature detecting unit 213 is a resistor which is formed on the fixing surface of the first carrier 212 to which the red laser diode 211 is fixed and which includes metal wiring. The first temperature detecting unit 213 functions as a thermistor, and by detecting its changing resistance value with a detection circuit (not illustrated), the control unit 30 can monitor the temperature in the vicinity of the red laser diode 211.

The green light-emitting module 220 is mainly constituted of the green laser diode 221, a second carrier 222, and a second temperature detecting unit 223. The green laser diode 221 is fixed to a fixing surface being an upper surface of the second carrier 222 toward a side of the waveguide module 100. The green laser diode 221 emits green laser light at an intensity corresponding to the light emission control signal sent from the control unit 30. The green laser light emitted from the green laser diode 221 is incident on the second incidence end surface 121 of the first optical waveguide 110.

The second carrier 222 is a block body formed of a material with an electrical insulation property. The second temperature detecting unit 223 is a resistor which is formed on the fixing surface of the second carrier 222 to which the green laser diode 221 is fixed and which includes metal wiring similar to that of the first temperature detecting unit 213. The second temperature detecting unit 223 functions as a thermistor, and by detecting its changing resistance value with a detection circuit (not illustrated), the control unit 30 can monitor the temperature in the vicinity of the green laser diode 221.

The blue light-emitting module 230 is mainly constituted of the blue laser diode 231, a third carrier 232, and a third temperature detecting unit 233. The blue laser diode 231 is fixed to a fixing surface being an upper surface of the third carrier 232 toward a side of the waveguide module 100. The blue laser diode 231 emits blue laser light at an intensity corresponding to the light emission control signal sent from the control unit 30. The blue laser light emitted from the blue laser diode 231 is incident on the third incidence end surface 131 of the first optical waveguide 110.

The third carrier 232 is a block body formed of a material with an electrical insulation property. The third temperature detecting unit 233 is a resistor which is formed on the fixing surface of the third carrier 232 to which the blue laser diode 231 is fixed and which includes metal wiring similar to that of the first temperature detecting unit 213. The third temperature detecting unit 233 functions as a thermistor, and by detecting its changing resistance value with a detection circuit (not illustrated), the control unit 30 can monitor the temperature in the vicinity of the blue laser diode 231.

The carrier (first carrier 212, second carrier 222, or third carrier 232) of each light-emitting module (red light-emitting module 210, green light-emitting module 220, or blue light-emitting module 230) is bonded to the substrate 160 and integrated with the waveguide module 100. Note that one side surface of the waveguide module 100 to which each light-emitting module is bonded may have an anti-reflective coat and an SAC coat and one side surface on an opposite side where the exit end surface 112 is provided may have an anti-reflective coat. In addition, a bonding surface of each carrier with the substrate 160 may have an Au coat. Note that an arrangement relationship of the light-emitting module for each color relative to each optical waveguide is not limited to the above and may be arbitrary and, for example, the red light-emitting module 210 may be arranged so as to correspond to the third optical waveguide 130 and the blue light-emitting module 230 may be arranged so as to correspond to the first optical waveguide 110.

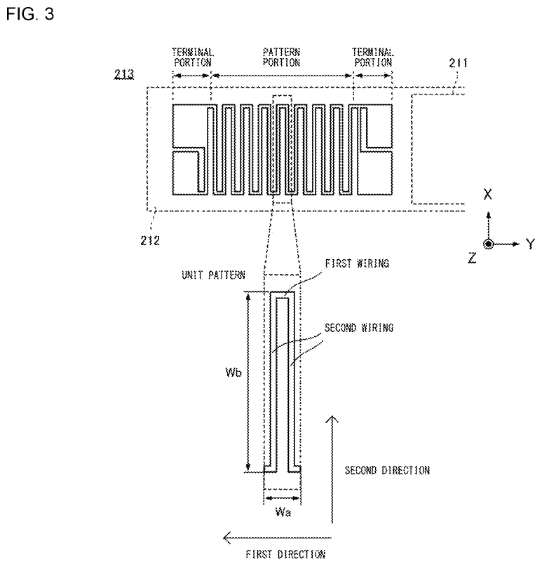

Next, details of the temperature detecting unit will be described. In the first example, since the configurations of the first temperature detecting unit 213, the second temperature detecting unit 223, and the third temperature detecting unit 233 are identical, the first temperature detecting unit 213 will be described as a representative example. FIG. 3 is a diagram schematically showing the configuration of the first temperature detecting unit 213.

As described above, the first temperature detecting unit 213 is formed as a resistor that includes metal wiring on the fixing surface of the first carrier 212 to which the red laser diode 211 is fixed. Specifically, the first temperature detecting unit 213 includes: metal wiring as a pattern portion in which a plurality of unit patterns are arranged in a series in a first direction (negative Y-axis direction) away from the red laser diode 211, each unit pattern having a length component (=Wb) of a second wiring extending in a second direction (X-axis direction) perpendicular to the first direction that is longer than a length component (=Wa) of a first wiring extending in the first direction (in other words, Wb>Wa); and metal wiring as a terminal portion connected to both ends of the pattern portion, respectively.

The metal wirings are stacked on the fixing surface of the first carrier 212 with a thickness of 50 nm or more and less than 1000 nm. Platinum, gold, or tungsten are preferable as a material of the metal wirings and, additionally, titanium or tantalum may be interposed to enhance adhesion to the fixing surface of the first carrier 212.

The pattern portion according to the present example is constituted of identical unit patterns arranged in a continuous series along the first direction. Note that a pattern of a portion that connects to a terminal portion may be a part of a unit pattern. Since heat generated when light is emitted from the red laser diode 211 propagates along the first direction, when considering a resistance value per unit pattern, the resistance values increase sequentially from a unit pattern in proximity to the red laser diode 211. At this point, since each unit pattern satisfies a relationship expressed as Wb >Wa, the resistance value of the first temperature detecting unit 213 as a whole increases in stages with time. When output of the red laser diode 211 is suppressed and generated heat decreases, since the resistance values decrease sequentially from the unit pattern in proximity to the red laser diode 211, the resistance value of the first temperature detecting unit 213 as a whole decreases in stages with time. When changes in resistance values over time occur in stages in this manner, the control unit 30 can detect a precise temperature of the red laser diode 211 and can also detect such changes rapidly.

In addition, since a four-terminal method is preferable over a two-terminal method in order to accurately detect resistance values, in the present example, the terminal portion has four wiring terminals for detecting resistance values using the four-terminal method. In other words, there are two wiring terminals that branch off on a side of one end of the pattern portion and two wiring terminals that branch off on a side of another end of the pattern portion. The detection circuit (not illustrated) that detects resistance values also has a configuration that accommodates the four-terminal method.

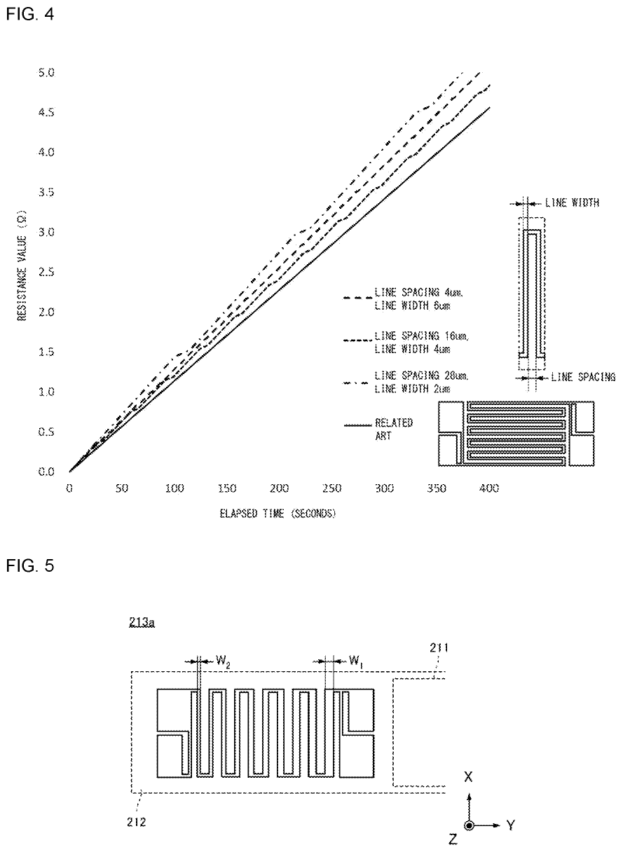

FIG. 4 is a graph showing a change in resistance values over time when using a temperature detecting unit according to related art and a temperature detecting unit (the first temperature detecting unit 213, the second temperature detecting unit 223, or the third temperature detecting unit 233) according to the present example. An axis of abscissa represents the passage of time (seconds) and an axis of ordinate represents a resistance value (Ω). The light-emitting module arranged adjacent to the temperature detecting unit maintains a light-emitting state throughout the elapsed time.

In addition, the temperature detecting unit according to the present example assumes three types of unit patterns. Specifically, a line width and line spacing in the first direction of the wiring were specified as illustrated, and three patterns were tested: a first pattern with 4 μm line spacing and 6 μm line width, a second pattern with 16 μm line spacing and 4 μm line width, and a third pattern with 28 μm line spacing and 2 μm line width. In addition, related art with a wiring pattern elongated in the first direction as illustrated was tested for comparison. In the drawing, a result of the first pattern is depicted by a dashed line, a result of the second pattern by a dotted line, a result of the third pattern by a dashed-dotted line, and a result of the related art by a solid line. The related art changes linearly, whereas the results from the first pattern to the third pattern appear to increase in a finely stepped manner. Furthermore, it can be seen that the first pattern to the third pattern have changed significantly compared to the related art.

While the pattern portion of the first temperature detecting unit 213 described in the present example is constituted of identical unit patterns arranged in a continuous series along the first direction, the respective unit patterns that constitute the pattern portion need not have identical shapes. Each unit pattern that constitutes the pattern portion may deform in various ways depending on how the detected resistance value is to change in response to temperature changes. Hereinafter, several modifications will be described.

FIG. 5 is a diagram schematically showing a configuration of a temperature detecting unit according to a first modification. Here, a first temperature detecting unit 213a according to a modification of the first temperature detecting unit 213 described above will be described.

Compared to each unit pattern that constitutes the pattern portion, a line width of wiring that extends in the second direction in the first temperature detecting unit 213a is wider the closer it is to the red laser diode 211. As illustrated, a line width W₁ of wiring extending in the second direction that is nearest to the red laser diode 211 is wider than a line width W₂ of wiring extending in the second direction that is farthest from the red laser diode 211 (W₁>W₂). The line width of each wiring extending in the second direction that are sandwiched between these wirings may be set so as to become gradually narrower or become narrower in a stepped manner the farther it is from the red laser diode 211. The pattern portion of the present first modification is set such that the resistance value increases the farther it is from the laser diode in the first direction. Therefore, even as the heat generated by the laser diode is transmitted in the second direction while being cooled by a heat dissipation effect of the first carrier 212, the increase in the resistance value across the entire temperature detecting unit can be made more uniform. In other words, a detection sensitivity to temperature changes (the amount of change in resistance value in response to temperature changes) can be made uniform across the entire pattern portion.

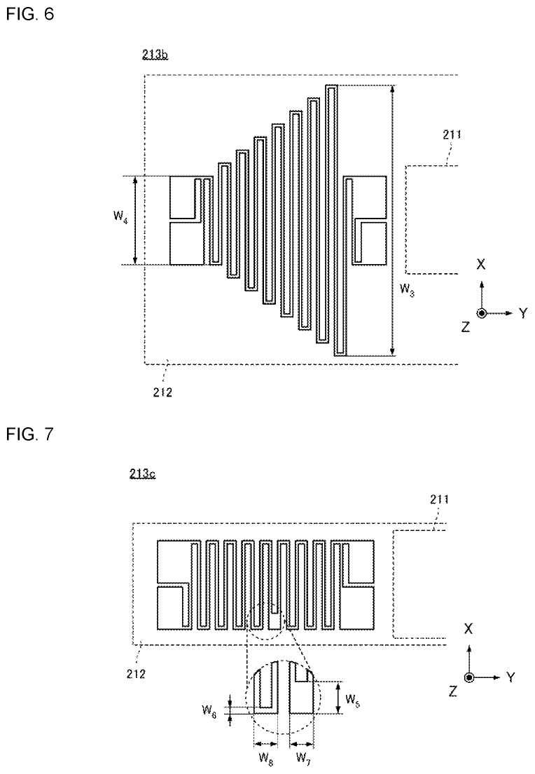

FIG. 6 is a diagram schematically showing a configuration of a temperature detecting unit according to a second modification. Here, a first temperature detecting unit 213b according to a modification of the first temperature detecting unit 213 described above will be described.

Compared to each unit pattern that constitutes the pattern portion, lengths of wiring that extends in the second direction in the first temperature detecting unit 213b is set longer the closer it is to the red laser diode 211. As illustrated, a length W₃ of wiring extending in the second direction that is nearest to the red laser diode 211 is longer than a length W₄ of wiring extending in the second direction that is farthest from the red laser diode 211 (W₃ >W₄). The length of each wiring extending in the second direction that are sandwiched between these wirings may be set so as to become gradually shorter or become shorter in a stepped manner the farther it is from the red laser diode 211. In addition, when comparing two wirings extending in the second direction and included in one unit pattern, a length of the wiring farther from the red laser diode 211 may be set shorter than a length of the wiring closer to the red laser diode 211. The pattern portion of the present second modification is set such that the resistance value increases the closer it is to the laser diode in the first direction. Therefore, as the laser diode generates heat and the heat is transmitted in the first direction with time, the amount of change in the resistance value increases near the laser diode that represents an initial stage of transmission. This makes it easier to capture changes immediately after the generation of heat. In other words, the detection sensitivity to temperature changes immediately after the start of heat generation can be increased.

FIG. 7 is a diagram schematically showing a configuration of a temperature detecting unit according to a third modification. Here, a first temperature detecting unit 213c according to a modification of the first temperature detecting unit 213 described above will be described.

In the first temperature detecting unit 213c, at least one line width of a connection wiring along the first direction which connects each unit pattern constituting the pattern portion is set wider than the line widths of the other wirings in the unit pattern. For example, as shown in the enlarged view of FIG. 7, a line width W₅ of a given wiring connection is wider than a line width W₆ of other wiring connections (W₅>W₆). In addition, a length W₇ of wiring extending in the first direction may be set longer than a length W₈ of other wirings extending in the first direction (W₇>W₈). the number of wirings with wide line widths or long lengths may not be limited to one and, for example, a plurality of wirings with wide line widths or long lengths may be set periodically. In the present third modification, the resistance value may be locally reduced or increased by arbitrarily changing the width W₅ and the length W₇ of the wirings. Accordingly, a change in the resistance value when heat generated by the laser diode is being transmitted can be made smaller or larger at any location. As a result, the detection sensitivity at any location can be adjusted and highly accurate temperature detection can be performed.

In addition, the first to third modifications need not necessarily be adopted individually and may be combined as appropriate. For example, in the pattern portion of the first modification shown in FIG. 5, locations where the line width and the line length vary as in the third modification may be provided locally or periodically at any desired location. Accordingly, a combined effect of both modifications can be achieved.

If each light-emitting module is to include the temperature detecting unit described above, the temperature of adjacently arranged laser diodes can be accurately detected. For example, the control unit 30 acquires a resistance value of each temperature detecting unit detected by the detection circuit and converts the resistance value into a temperature by referring to a lookup table set in advance. In particular, since the temperature detecting unit according to the present example is capable of detecting a temperature change with higher accuracy, the control unit 30 can rapidly realize output control of the laser diode in response to temperature.

In addition, instead of conversion into temperature using a lookup table, the temperature may be estimated using a counter. Specifically, by incrementing or decrementing the counter each time the amount of change in the resistance value per unit time exceeds a predetermined threshold, a temperature change since measurement began can be estimated in a simple manner based on the change in the counter value. Generally, since dimensional variations occur during the manufacturing of the pattern portion, variations in the amount of change in the resistance value due to temperature changes also occur. Depending on a magnitude of the dimensional variation, it may be necessary to configure lookup tables individually. On the other hand, by performing temperature estimation using a counter, a decline in temperature detection accuracy can be mitigated and an amount of temperature change can be estimated without requiring individual initial settings.

In particular, since the projector 40 according to the present example described using FIG. 1 adjusts output of each laser diode according to the temperature detected by each temperature detecting unit, if the temperature can be detected accurately, the emission intensity of each laser diode can be brought closer to a target value. Since the light emitted from each laser diode is mixed in an optical waveguide and emitted as mixed-color light, if the emission intensity of each laser diode is close to the target value, an image represented by an external signal can be reproduced more faithfully on the screen 50.

As optical devices configured by combining a waveguide module and a light-emitting module, various configurations exist in addition to the configuration of the optical device 10 described as the first example. Even with such optical devices with other configurations, it is effective for the light-emitting module to include a temperature detecting unit having a pattern portion as described above. As an example, a second example will be described below.

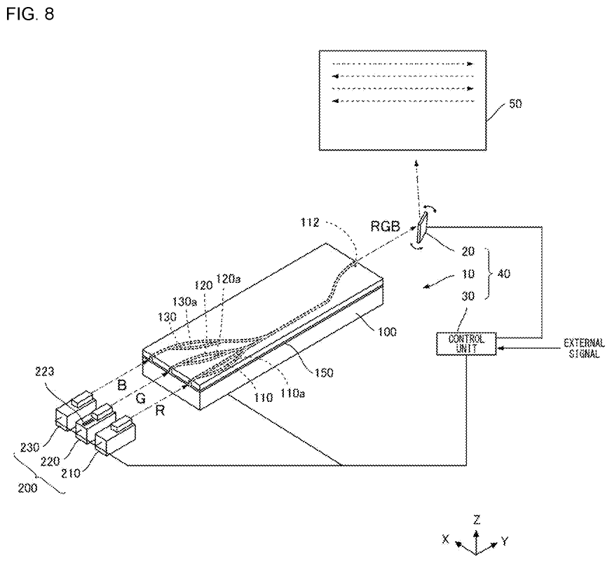

FIG. 8 is a schematic view illustrating a configuration of the projector 40 adopting the optical device 10 according to the second example of the present example embodiment. In the second example, while the same reference numerals will be used for elements identical or corresponding to those in the first example, elements with a different configuration from the first example will be described individually. In addition, description of similar elements to the first example will not be repeated.

The first optical waveguide 110 has a first optical waveguide branch 110a which branches from the first optical waveguide 110 on an incidence side of the junction where the first optical waveguide 110 merges with the second optical waveguide 120 and the third optical waveguide 130 and which then merges once again with the first optical waveguide 110. The first optical waveguide branch 110a is provided with a voltage applying unit (not illustrated) that operates according to a control signal of the control unit 30. By controlling the voltage of the voltage applying unit, the control unit 30 changes a phase of red laser light propagating along the first optical waveguide branch 110a and adjusts light intensity of the red laser light after the convergence.

The second optical waveguide 120 has a second optical waveguide branch 120a which branches from the second optical waveguide 120 on an incidence side of the junction where the second optical waveguide 120 merges with the first optical waveguide 110 and the third optical waveguide 130 and which then merges once again with the second optical waveguide 120. The second optical waveguide branch 120a is provided with a voltage applying unit (not illustrated) that operates according to a control signal of the control unit 30. By controlling the voltage of the voltage applying unit, the control unit 30 changes a phase of green laser light propagating along the second optical waveguide branch 120a and adjusts light intensity of the green laser light after the convergence.

The third optical waveguide 130 has a third optical waveguide branch 130a which branches from the third optical waveguide 130 on an incidence side of the junction where the third optical waveguide 130 merges with the first optical waveguide 110 and the second optical waveguide 120 and which then merges once again with the third optical waveguide 130. The third optical waveguide branch 130a is provided with a voltage applying unit (not illustrated) that operates according to a control signal of the control unit 30. By controlling the voltage of the voltage applying unit, the control unit 30 changes a phase of blue laser light propagating along the third optical waveguide branch 130a and adjusts light intensity of the blue laser light after the convergence.

In other words, by controlling the voltage of each voltage applying unit, the control unit 30 adjusts target mixed-color light. For example, by providing a monitor output that outputs mixed-color light or monochromatic light at a location other than the exit end surface 112 as described above, the control unit 30 can adjust the voltage of each voltage applying unit so as to output desired light while monitoring the monitor output as feedback. Therefore, the control unit 30 primarily controls on/off switching of the laser diode for each light-emitting module.

Specifically, the control unit 30 stops light emission of the laser diode or restricts light intensity output by the laser diode when the light-emitting module reaches a high temperature equal to or higher than a certain temperature. When performing such control, not all light-emitting modules need to be equipped with a temperature detecting unit and only one light-emitting module may be equipped with a temperature detecting unit. In the light-emitting modules according to the second example, the green light-emitting module 220 includes the second temperature detecting unit 223 but the red light-emitting module 210 and the blue light-emitting module 230 do not include temperature detecting units. In the optical device 10 according to the second example, the control unit 30 stops light emission of the green, red, and blue laser diodes or restricts light intensity output by the laser diodes based on a signal from the temperature detecting unit of the green light-emitting module 220. Therefore, both a simple configuration and stable light emission control based on the temperature of a light-emitting module can be realized.

Note that the light-emitting module including the second temperature detecting unit 223 in the second example need not be the green light-emitting module 220. For example, an emitted color of the light-emitting module including the second temperature detecting unit 223 may be arbitrarily set based on a comparison of light emission efficiency, reliability, and temperature characteristics among the green light-emitting module 220, the red light-emitting module 210, and the blue light-emitting module 230.

In addition, while the control unit 30 performs control to stop output of laser diodes in the second example, the control unit 30 is not limited thereto and may be configured to adjust light intensity output by the laser diode of each light-emitting module in a similar manner to the first example. When the control unit 30 determines that a temperature of a light-emitting module is equal to or exceeds a predetermined temperature based on a signal from the temperature detecting unit of the light-emitting module, the control unit 30 may arbitrarily control light intensity output by the laser diode of each of three colors according to processing set in advance. In a similar manner, even in the first example, based on an output signal from the temperature detecting unit in any one light-emitting module, the control unit 30 may stop output or adjust output light intensity including the laser diodes mounted to the other two light-emitting modules. Accordingly, a color mixing balance can be prevented from changing due to temperature changes in a simple manner.

In addition, while the optical device 10 has been described as being constituted of the waveguide module 100 and the light-emitting module 200 in the present example embodiment, the optical device 10 may be configured by adding the control unit 30 thereto.

1. A light-emitting module, comprising:
a carrier;
a laser diode fixed to one surface of the carrier; and
a temperature detecting unit that is formed on the one surface and includes a unit pattern including a first wiring extending in a first direction away from the laser diode in a planar direction of the one surface and a second wiring connected to the first wiring, extending in a second direction perpendicular to the first direction, and having a length in the second direction being longer than a length of the first wiring in the first direction.

2. The light-emitting module according to claim 1, wherein the temperature detecting unit has at least two or more unit patterns arranged in a series along the first direction.

3. The light-emitting module according to claim 2, wherein when comparing the plurality of unit patterns, a line width of the second wiring in the first direction is set wider the closer to the laser diode.

4. The light-emitting module according to claim 2, wherein when comparing the plurality of unit patterns, a length of the second wiring in the second direction is set longer the closer to the laser diode.

5. The light-emitting module according to claim 2, wherein when comparing the plurality of unit patterns, a line width of at least one first wiring in the second direction is wider than a line width of another first wiring in the second direction.

6. The light-emitting module according to claim 5, wherein a length in the first direction of the first wiring that is wider than the line width of the other first wiring in the second direction is longer than a length of the other first wiring in the first direction.

7. The light-emitting module according to claim 1, wherein the first wiring or the second wiring is made of platinum, gold, or tungsten.

8. The light-emitting module according to claim 6, wherein a thickness of the first wiring or the second wiring is 50 nm or more and less than 1000 nm.

9. The light-emitting module according to claim 1, wherein the temperature detecting unit has four terminals.

10. An optical device, comprising:
at least one light-emitting module according to claim 1;
a waveguide module including a waveguide layer having an optical waveguide that propagates light emitted from the laser diode; and
a control unit configured to control light intensity output by the laser diode based on a signal from the temperature detecting unit in the light-emitting module.

11. The optical device according to claim 10, wherein
the light-emitting module includes a first light-emitting module including a first laser diode that emits red light, a second light-emitting module including a second laser diode that emits green light, and a third light-emitting module including a third laser diode that emits blue light, and
the control unit controls light intensity output by each of the first to third laser diodes based on a signal from the temperature detecting unit mounted to any one of the first to third light-emitting modules.

12. The optical device according to claim 10, wherein
the laser diode in the light-emitting module is configured to emit any of red light, green light, and blue light,
the light-emitting module includes: a first module including the laser diode that emits one of two remaining colors among the red light, green light and the blue light, and the carrier; and
a second module including the laser diode that emits the other one color that differs from the one color of the two colors and the carrier, and the control unit controls light intensity output by the laser diode of the light-emitting module, the laser diode of the first module, and the laser diode of the second module, respectively, based on a signal from the temperature detecting unit included in the light-emitting module.
